(19) United States
(12) Patent Application Publication
(10) Pub. No.: US 2024/0297718 A1
(43) Pub. Date: Sep. 5, 2024

(54) SYSTEM AND METHOD FOR SOLAR CELL PHOTO-LUMINESCENCE MODULATION

(71) Applicant: Purdue Research Foundation, West Lafayette, IN (US)

(72) Inventor: Walter Daniel Leon-Salas, West Lafayette, IN (US)

(73) Assignee: Purdue Research Foundation, West Lafayette, IN (US)

(21) Appl. No.: 18/596,455

(22) Filed: Mar. 5, 2024

Related U.S. Application Data
(60) Provisional application No. 63/450,052, filed on Mar. 5, 2023.

(51) Int. Cl. H04B 10/54; H01L 31/0693; H02J 7/35

(52) U.S. Cl. CPC H04B 10/541; H01L 31/0693; H02J 7/35; H02J 2300/24

(57) ABSTRACT

A system may include a solar cell and a modulator connected to an output of the solar cell. The system may receive a signal. When the signal being in a first state corresponding to modulation, the modulator may modulate voltage output of the solar cell and cause the solar cell to perform optical transmission. When the signal is in a second state corresponding to energy harvesting, the modulator to cease modulation of the output of the solar cell.

### CROSS REFERENCE TO RELATED APPLICATIONS

This application claims the benefit of U.S. Provisional Application No. 63/450,052 filed Mar. 5, 2023. the entirety of which is hereby incorporated by reference.

### GOVERNMENT RIGHTS

This invention was made with government support under ECCS-1809637 awarded by the National Science Foundation. The government has certain rights in the invention.

### TECHNICAL FIELD

This disclosure relates to optical communications and, in particular, to photo-luminescent radiation of solar cells.

### BACKGROUND

The use of solar cells as photo-receptors in receivers for visible light communications allows using a solar cell for multiple purposes, namely to harvest ambient radiant energy and to receive data wirelessly, savings in costs and space will be achieved, which would be advantageous for Internet-of-Things (IoT) applications. This approach was further extended to use GaAs solar cells as light emitters for data transmission. In this technique, dubbed Optical Frequency Identification (OFID), the electro-luminescent (EL) and photo-luminescent (PL) radiation of GaAs solar cells is modulated to transmit information wirelessly. Due to their direct bandgap electronic structure, GaAs solar cells have strong EL and PL emissions in the near infrared (NIR), peaking around 860 nm, which can be detected using a Si photo-diode or a CMOS camera.

### BRIEF DESCRIPTION OF THE DRAWINGS

The embodiments may be better understood with reference to the following drawings and description. The components in the figures are not necessarily to scale. Moreover, in the figures, like-referenced numerals designate corresponding parts throughout the different views.

FIG. 1 illustrates a system for modulating PL transmission from a solar cell.

FIG. 2 illustrate an equivalent circuit for a system for modulating PL transmission from a solar cell.

FIG. 3 illustrates a numerical solution of a modulator circuit.

FIG. 4 illustrates an experimental setup to characterize PL irradiance from a GaAs solar cell.

FIG. 5 illustrates a characterization of PL irradiance from a GaAs solar cell.

FIG. 6 illustrates an experimental setup to characterize modulation speed of an on-off modulator.

FIG. 7 illustrates acquired waveforms for an on-off modulator.

FIG. 8 illustrates an equivalent circuit for the analysis of an on-off PL modulator.

FIG. 9 illustrates measured and calculated voltage across a solar cell after it has been short circuited.

FIG. 10 illustrates voltage across a solar cell and output voltage of optical receiver as the solar cell's internal capacitance charges up.

FIG. 11 illustrates acquired waveforms when a system for modulating PL transmission from a solar cell was used to modulate the solar cell voltage with a ramp waveform.

FIG. 12 illustrates acquired waveforms at the output of the optical receiver as is modulated with a square pulse with voltage excursion.

FIG. 13 illustrates acquired waveforms from a PL-based optical communication system that uses a system for modulating PL transmission.

### DETAILED DESCRIPTION

The use of solar cells as photo-receptors in receivers for visible light communications has been explored before. The motivation for this approach is that by using a solar cell for two purposes, namely to harvest ambient radiant energy and to receive data wirelessly, savings in costs and space will be achieved, which would be advantageous for Internet-of-Things (IoT) applications. This approach was further extended to use GaAs solar cells as light emitters for data transmission. In this technique, dubbed Optical Frequency Identification (OFID), the electro-luminescent (EL) and photo-luminescent (PL) radiation of GaAs solar cells is modulated to transmit information wirelessly. Due to their direct bandgap electronic structure, GaAs solar cells have strong EL and PL emissions in the near infrared (NIR), peaking around 860 nm, which can be detected using a Si photo-diode or a CMOS camera. In order to modulate the luminescence of a solar cell, it is necessary to vary the voltage across its terminals because the luminescent optical power emitted by a solar cell is a function of its voltage.

The basic PL modulator is a MOSFET that works as a switch to short the terminals of the solar cell or leave them in open circuit (OC), thus, setting the cell's voltage to either 0 V or to the OC voltage (V_{oc}). While simple to implement, this type of on-off modulator fully discharges the solar cell's internal capacitance while it is being shorted. This capacitance needs to be re-charged before the next symbol can be transmitted. The time to re-charge this internal capacitance is a function of the luminous flux falling on the solar cell and the area of the solar cell.

An improved PL modulator that exploits the relationship between the input impedance of a boost DC-DC converter and the duty cycle of its clock input was employed to change the voltage across the solar cell and modulate the solar cell's PL. This approach allows the existence of modulation levels between short and OC voltages, thus, it is possible to use it with Mary modulation and also to avoid fully shorting the solar cell. However, due to the large input capacitance of a boost DC-DC converter, the modulation speed of this modulator is limited to few kilobits per second (kbps). Moreover, the switching action of the DC-DC converter introduces ripple noise, which would be of concern for M-ary modulation.

This paper presents a circuit suitable for the modulation of the PL radiation of GaAs solar cells. The circuit uses a MOSFET and a low-power operational amplifier (opamp) in a feedback loop and works as a variable load to the solar cell. By controlling the current drawn from the solar cell, the proposed modulator is able to set the solar cell's voltage to a target value between 0 V and V_{oc}. This circuit allows M-ary modulation and does not require a full discharge of the solar cell's internal capacitance. Hence, it can achieve higher speeds than an on-off modulator. Moreover, it does not introduce ripple noise.

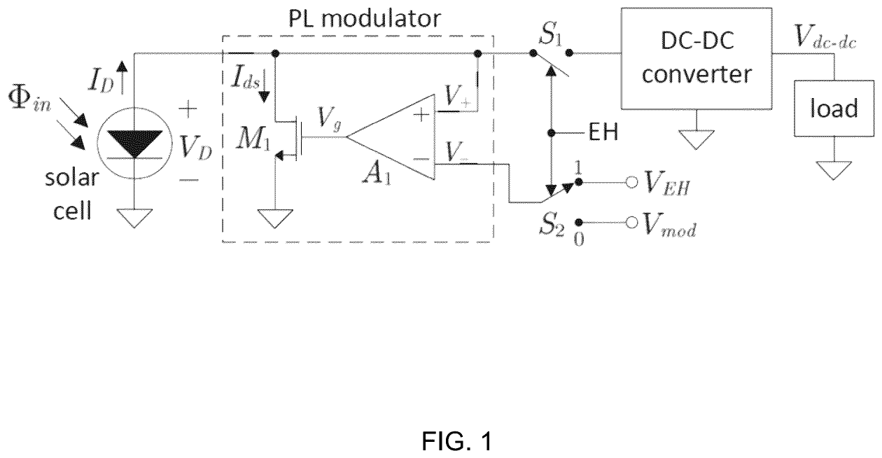

FIG. 1 illustrates a system for modulating PL transmission from a solar cell. This system can set the voltage across the solar cell to any value between 0 V and V_{oc} using the feedback loop formed by a MOSET (M₁) and an opamp (A₁) connected together. The modulator may connect to a DC-DC converter. The system may include a modulation switch (S₁) and a load switch (S₂), which is driven by an input signal (EH). When EH is high (energy harvesting mode), the switch S₁ closes and the solar cell gets connected to the DC-DC converter allowing power to be drawn from the solar cell and get transferred to a load. Moreover, during energy harvesting mode, S₂ connects the negative input terminal of the opamp (V_) to V_{EH}, which is a voltage greater than V_{oc}. This causes the opamp's output to drop to 0 V turning off M₁. With M₁ off, all of the solar cell's output current flows into the DC-DC converter and maximum power from the solar cell can be harvested. V_{EH} can be connected to the output of a boost DC-DC converter.

When the signal EH is low (modulation mode), S₁ opens disconnecting the modulator from the DC-DC converter while V_ gets connected to the modulation input V_{mod}. The feedback loop forces V_{D} to follow V_{mod} by controlling M₁'s drain to-source current I_{ds}. In this manner, M₁ effectively appears as a variable load to the solar cell. Since in this mode the modulator is fully disconnected from the DC-DC converter, switching noise from the DC-DC converter does not affect modulation. However, energy cannot be harvested during this mode. Thus, this modulator is suitable for burst transmission.

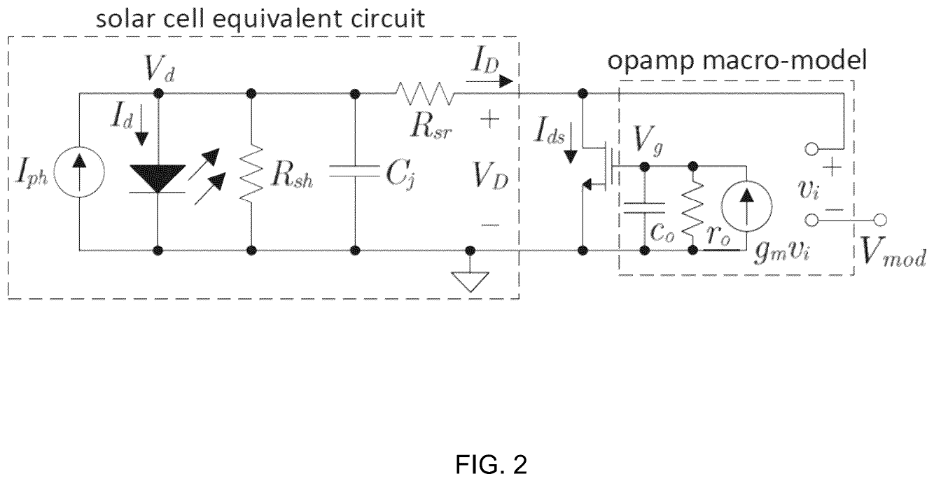

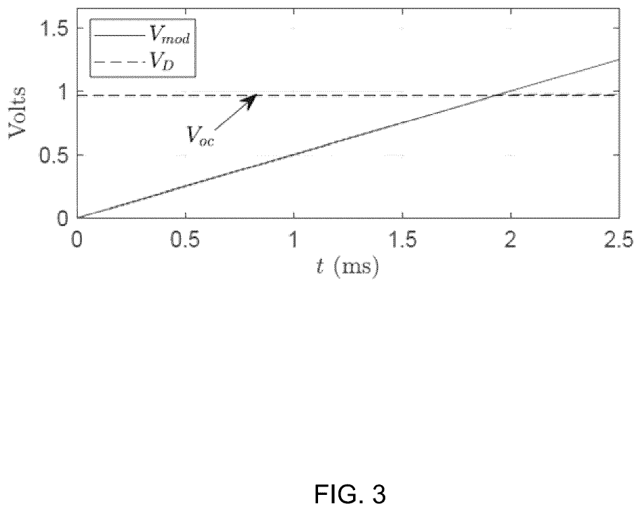

FIG. 2 illustrate an equivalent circuit for the system. In order to verify the operation of this feedback loop, the equivalent circuits of the modulator and the solar cell shown in FIG. 2 were used to analyze the modulator. The following equations were derived from this circuit:

$$\frac{dV \text{?}}{dt} = \frac{{A}_{o}}{{r}_{o} {c}_{o}} ( {V}_{D} - V \text{?} ) - \frac{1}{{r}_{o} {c}_{o}} {V}_{g} \qquad ( 1 )$$

$$\frac{{dV}_{D}}{dt} = \frac{I \text{?} + I \text{?}}{{C}_{j}} - \frac{I \text{?}}{{C}_{j}} e \text{?} - \frac{1}{R \text{?} C \text{?}} {V}_{D} - \frac{I \text{?}}{{C}_{j}}$$

$$\text{?} \text{indicates text missing or illegible when filed}$$

where, rₒCₒ=Aₒ/(2π×GB), gₘ=Aₒ/rₒ, Aₒ is the opamp's DC gain and GB is its gain-bandwidth product. Three regions of operation for M₁ were considered (sub-threshold, saturation and triode). Thus, Iₐₛ was modeled as follows:

$$I \text{?} \{ \begin{matrix}{I}_{O} \frac{W}{L} e ( \text{?} ) / n \text{?} & if {V}_{g} < {V}_{TH} \\ \frac{β}{2} {( {V}_{g} - {V}_{TH} )}^{2} & if {V}_{D} \geq {V}_{g} - {V}_{TH} \\ β ( ( {V}_{g} - {V}_{TH} ) {V}_{D} - \frac{{V}_{D}^{2}}{2} ) & if {V}_{D} < {V}_{g} - {V}_{TH}\end{matrix} \qquad ( 2 )$$

$$\text{?} \text{indicates text missing or illegible when filed}$$

where, V_{TH} is the threshold voltage of the transistor, W/L its width-length ratio and β its transconductance. The set of equations was solved numerically. FIG. 3 shows the solution for V_{D} as V_{mod} increases linearly for the following parameter values: V_{TH}=0.85 V, GB=500 kHz, Ao=90 dB, β=0.48 S, W/L=10, 000 and Io=10 nA. Notably, V_{D} follows V_{mod} until it reaches V_{oc}. As V_{mod} increases beyond V_{oc}, V_{g} goes to 0 V and M₁ is turned off, leaving the solar cell in OC.

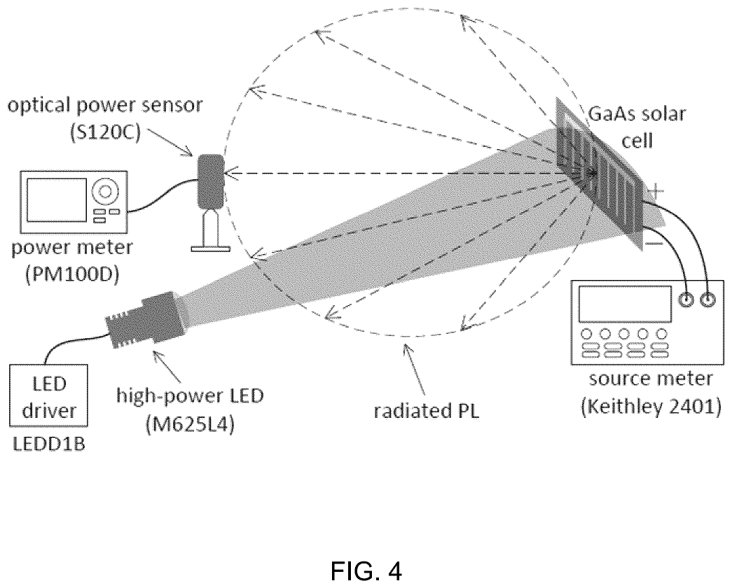

FIG. 4 illustrates an experimental setup to characterize PL radiated by a solar cell. The luminescent radiation emitted by a solar cell is the product of radiative recombination of electron-hole pairs inside the solar cell. For GaAs, which has a bandgap energy of 1.42 eV, the emitted luminescent photons are in the near infrared (NIR) band (peaking at wavelength of approximately 873 nm). For an ideal solar cell (without losses), the emitted luminescence should exactly balance the incoming light. A counter-intuitive result is that efficient external luminescence is a necessary condition for approaching the Shockley-Queisser limit. Thus, a good solar cell also needs to be designed to be a good light emitting diode (LED). It has also been shown that a reflective back contact improves the external luminescence of a solar cell [17]

If the solar cell is kept in OC, energetic electrons in the conduction band must remain inside the cell. Eventually most of these electrons recombine radiatively emitting photons. Thus, in OC the radiated PL is at its maximum and, for efficient GaAs solar cells, it can be readily detected with a CMOS camera. If a short circuit (SC) is applied to the solar cell, the majority of the electrons inside the cell leave and flow through the external circuit. In this case, the PL radiated by the solar cell is greatly reduced since only a small fraction of the photo-generated electrons remain in the solar cell and are available for radiative recombination.

An experimental setup depicted in FIG. 4 was built to characterize the PL radiated by a solar cell. A GaAs solar cell from Alta Devices was employed in this work. These solar cells have a record efficiency of 29% achieved with the help of a reflective back contact, which enhances photon recycling. A high-power LED with an spectrum peaking at 625 nm was used to illuminate the solar cell in order to stimulate a PL response. The solar cell was illuminated with an irradiance of 1.99 μW/cm². The PL irradiance, Eₚₗ, was measured using an optical power sensor at a distance of 30 cm from the solar cell as the voltage across the solar cell was varied from 0 V to the OC voltage (V_{oc}=0.964 V). The voltage across the solar cell was varied in discrete increments using a source meter. A long pass optical filter with a cutoff wavelength of 800 nm was placed in front of the optical power sensor to block light from the LED. In order to obtain repeatable results, this setup was placed inside an enclosure to block ambient light.

Using the reciprocity relation, it can be shown that the luminescent optical power emitted by the solar cell is an exponential function of the voltage across the solar cell V_{D}. Hence, Eₚₗ, can be modeled as follows:

$$E \text{?} = E \text{?} + E \text{?} ( e \text{?} - 1 ) \qquad ( 3 )$$

$$\text{?} \text{indicates text missing or illegible when filed}$$

where, Eₒ, Eₛ and n are model parameters. In particular, Eₒ is the SC irradiance, n is an ideality factor and V_{T} is the thermal voltage. The values of the model parameters can be estimated by curve fitting (3) to measured data.

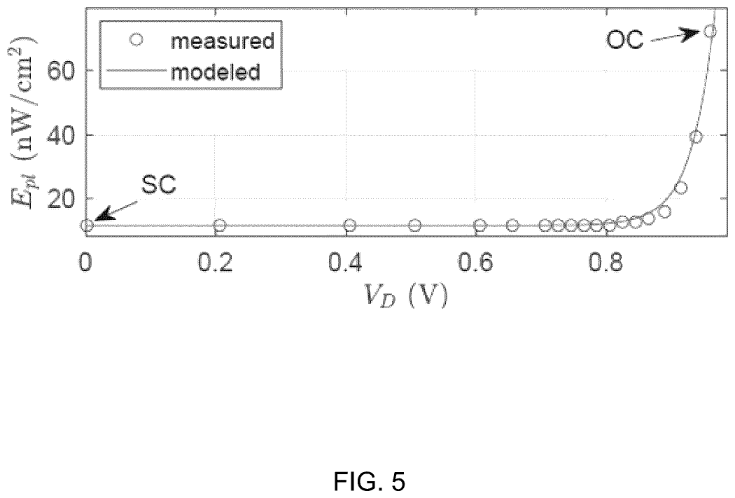

FIG. 5 illustrates the measured and modeled irradiance from the solar cell. The values of the estimated model parameters are: E₀=1.17×10⁻⁸ W/cm², Eₛ=2.90×10⁻¹⁹ W/cm² and n=1.375. In the figure, the SC and OC points are marked. Notably, the PL irradiance is an exponential function of the voltage across the solar cell V_{D}.

This result shows that in order to modulate the emitted PL irradiance, one must vary V_{D}. The most basic modulator is an on-off modulator implemented using a switch. The switch used to short the terminals of the solar cell (V_{D}=0 V) or leave them in OC (V_{D}=V_{oc}). Although simple, the drawback of this modulator is that, during SC, it fully discharges the solar cell's internal capacitance. Recharging this capacitance takes some time and results in a delayed PL response, which ultimately limits the maximum modulation rate.

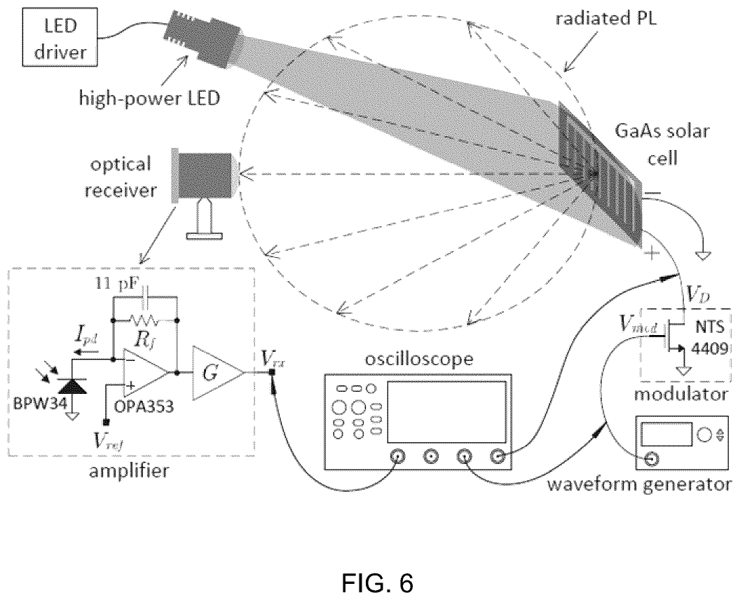

FIG. 6 illustrates an experimental setup to characterize the modulation speed of an on-off modulator. To characterize the charging time of the solar cell's internal capacitance, the setup shown in FIG. 6 was built. The solar cell was illuminated using the same conditions employed in the characterization shown in FIG. 4. An optical receiver was placed in front of the solar cell at a distance of 30 cm and the on-off modulator was implemented using a MOSFET to periodically short the terminals of the solar cell. The optical receiver comprised a focusing lens, a photo-diode and an amplifier.

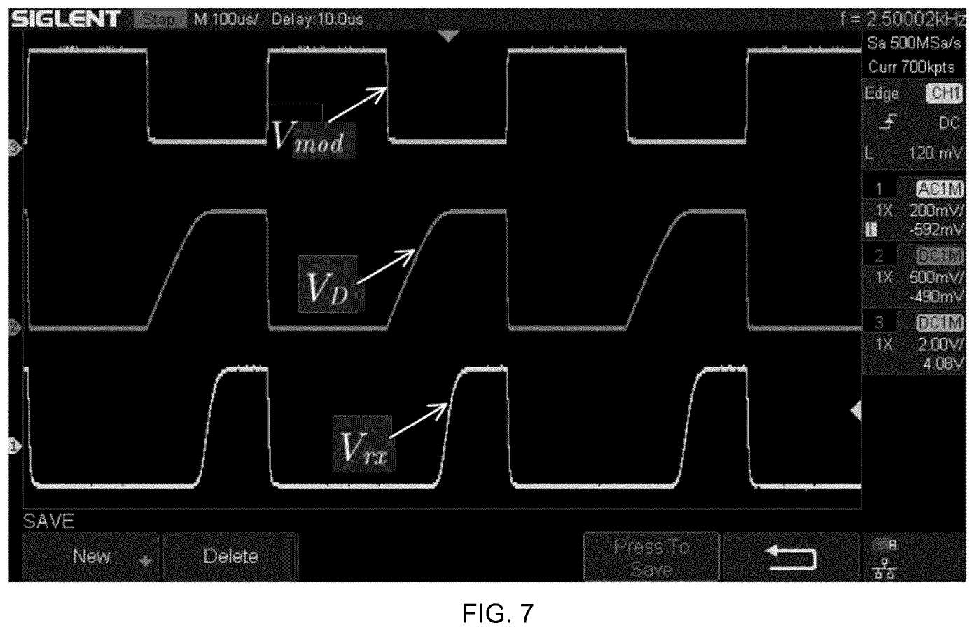

FIG. 7 illustrates acquired waveforms from the on-off modulator. V_{mod} drives the MOSFET's gate, V_{D} is the voltage across the solar cell, and Vᵣₓ is the optical receiver's output. When V_{mod} is high, the MOSFET turns on and shorts the terminals of the solar cell, as a consequence V_{D} collapses to 0 V. When V_{mod} is low, the MOSFET turns off and V_{D} raises up to V_{oc} as the solar cell's internal capacitance gets re-charged by the cell's photo-generated current. It can be seen that it takes about 0.1 ms for this re-charging to complete (under the conditions stated above). Moreover, due to the non-linear relationship between Eₚₗ and V_{D}, Vᵣₓ does not change until V_{D} is sufficiently high. Due to these factors the maximum transmission speed that can be achieved with the on-off modulator is limited to about 5 kbps (when pulse position modulation is used).

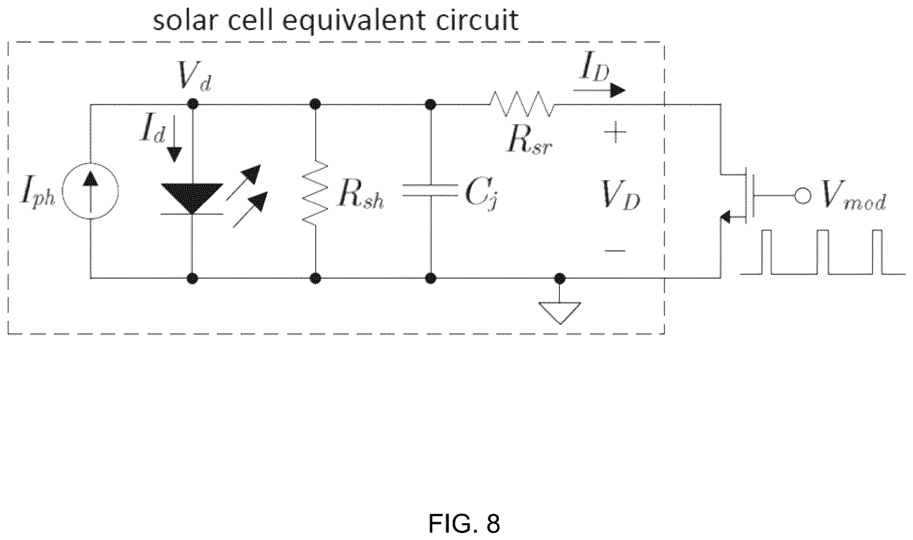

To gain insight into the limiting factors of the on-off modulator, a circuit analysis was performed. FIG. 8 illustrates an equivalent circuit of an on-off PL modulator. In this equivalent circuit, Iₚₕ is the photo-generated current, Rₛₕ is the shunt resistance that models the load presented to the current generated near the edges of the solar cell, Cⱼ is the junction capacitance and Rₛᵣ is the series resistance due to device contacts and connections. The diode models the behaviour of the solar cell's pn junction. In our case, this diode is also an LED responsible for the NIR luminescent radiation. The current through this diode is given by Shockley's equation: I_{d}=Iₛ(e^{Vd/nVT} −1), where Iₛ is the solar cell's reverse saturation current.

Using the circuit in FIG. 8 and considering that Rₛᵣ≈0, which results in V_{d} ≈V_{D}, the differential equation in (4) was derived and solved using numerical methods.

$$\frac{{dV}_{D}}{dt} = \frac{I \text{?} + I \text{?}}{{C}_{j}} - \frac{I \text{?}}{{C}_{j}} ϵ \text{?} - \frac{1}{R \text{?} C \text{?}} {V}_{D} \qquad ( 4 )$$

$$\text{?} \text{indicates text missing or illegible when filed}$$

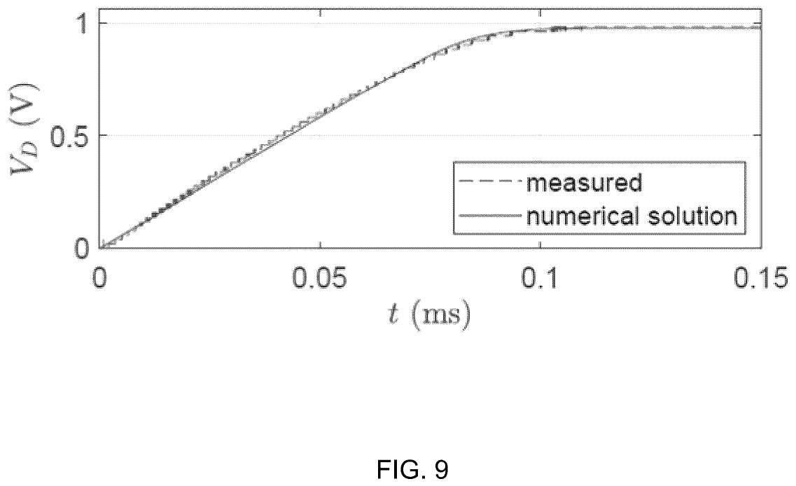

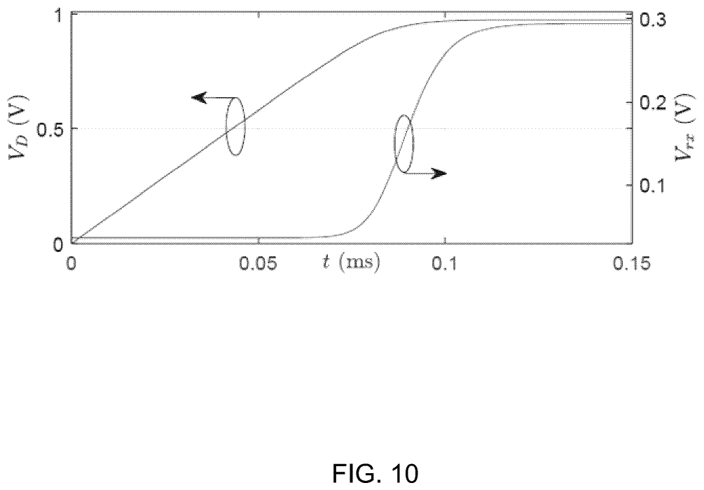

FIG. 9 shows the measured waveform and the numerical solution for the solar cell's voltage for an initial condition of V_{D}=0 V (SC) and for Iₚₕ=8.2 mA, Rₛₕ=6.57 kΩ and Cⱼ=700 nF. Notably, V_{D} increases steadily, as the internal junction capacitance charges up, until it reaches the OC voltage (V_{oc}=0.964 V). FIG. 10 illustrates voltage across the solar cell, V_{D}, and output voltage of optical receiver, Vᵣₓ, as the solar cell's internal capacitance charges up from SC.

The output of the receiver's amplifier, Vᵣₓ, is a linear function of the photo-current Iₚₕ and can be calculated as follows:

$$V \text{?} = I \text{?} \times R \text{?} \times G \qquad ( 5 )$$

$$\text{?} \text{indicates text missing or illegible when filed}$$

where, R_{f} is the feedback resistor and G is the gain of the second stage of the amplifier. Moreover, Iₚₕ=PᵣₓR_{λ}, where Pᵣₓ is power received by the optical receiver and R_{λ} is responsivity of the receiver's photo-diode. Pᵣₓ can be estimated from the irradiance using:

$$P \text{?} = A \text{?} \times E \text{?} \qquad ( 6 )$$

$$\text{?} \text{indicates text missing or illegible when filed}$$

where, Aₗₑₙₛ is the area of the receiver's lens. Combining the solution of (4) with (3), (5) and (6), the receiver's output Vᵣₓ was estimated and is shown in FIG. 3 (for R_{f}=100 kΩ, G=10, Aₗₑₙₛ=5.07 cm² and R_{λ}=0.68 A/W). This result matches well with the acquired waveforms shown in FIG. 7 and it also shows that Vᵣₓ starts to rise only after V_{D} has risen above 0.835 V or about 86% of V_{oc}. This delayed response in Vᵣₓ is due to the non-linear and exponential relationship between the emitted PL and V_{D}. It also suggests that an improved PL modulator does not need to fully short circuit the solar cell to significantly change the solar cell's PL.

The functionality of the modulator was also verified experimentally using the test setup shown in FIG. 6 in which the on-off modulator was replaced with the proposed modulator. The proposed modulator was implemented using the NTS4409 MOSFET and the low-power TLV2761 opamp, which has a supply current consumption of 20 μA.

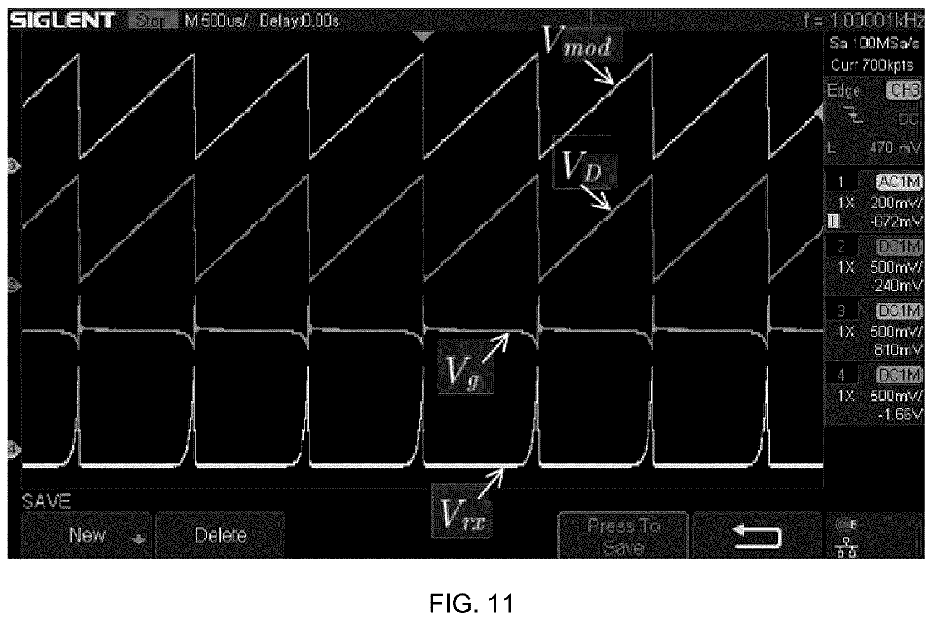

FIG. 11 shows acquired waveforms that demonstrate the expected operation of the modulator and validate the circuit analysis presented above. The figure also shows an exponential rise at Vᵣₓ corroborating the exponential relationship between V_{D} and solar cell's luminescent optical power.

Due to this exponential relationship, the receiver's output, Vᵣₓ, does not rise until V_{D} is sufficiently high. To establish the modulation amplitude that results in the fastest response for binary pulse modulation, the following experiment was carried out: V_{D} was modulated with a square pulse, with a voltage excursion from V_{low} to V_{oc}, and the receiver output Vᵣₓ was recorded.

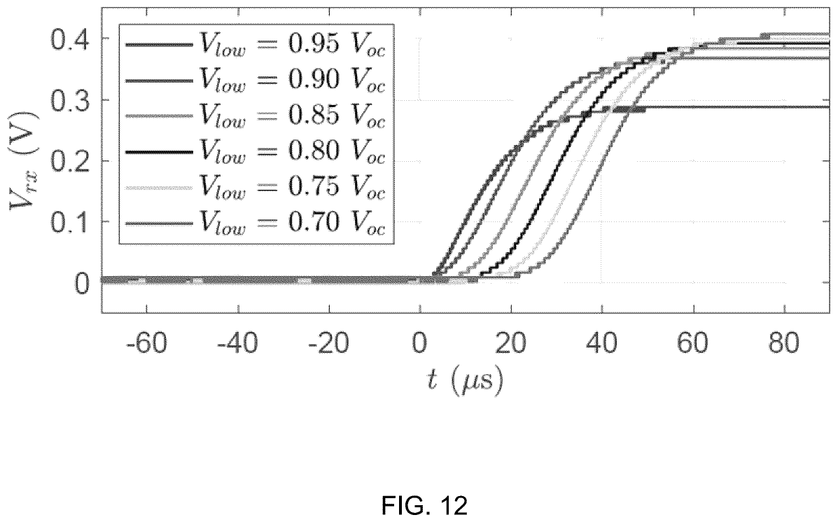

FIG. 12 illustrates acquired waveforms at the output of the optical receiver as VD is modulated with a square pulse with voltage excursion from Vlow to Voc. FIG. 12 shows the results of this experiment for different values of V_{low}. It can be seen that as V_{low} decreases, it takes longer for Vᵣₓ to start rising. On the other hand, if V_{low} is too high, i.e. 0.95 V_{oc}, the output pulse's amplitude decreases. A good compromise is to set V_{low} to 0.85 V_{oc} or 0.90 V_{oc}. In practice, V_{oc} is measured periodically as part of most maximum power point tracking algorithms.

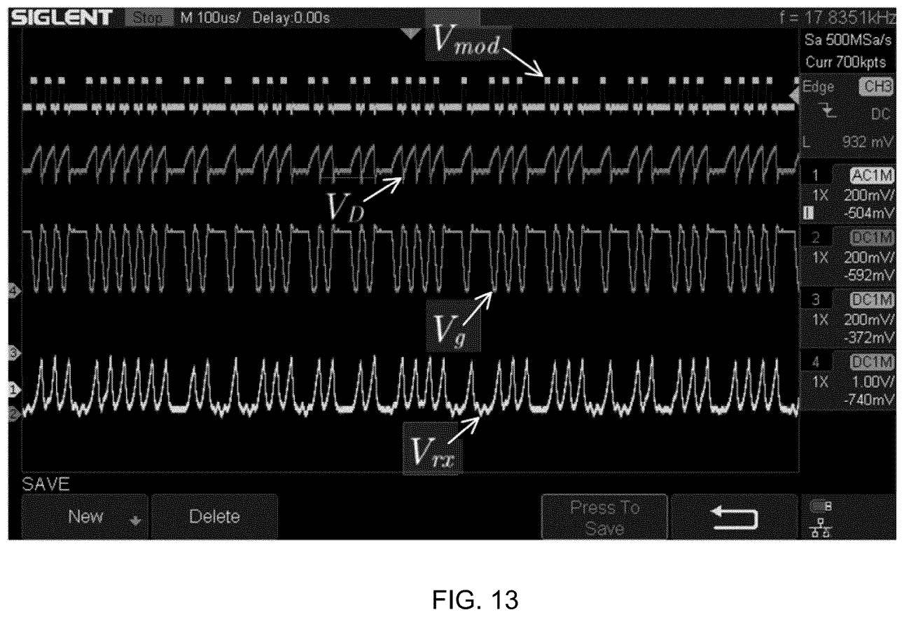

As a final test, the solar cell's luminescence was modulated with a random sequence of bits to assess the performance of a PL-based optical communication link using the proposed modulator. For this test, a binary differential pulse interval modulation (DPIM) scheme was employed as it has been shown to be advantageous for optical communications. In this scheme, the 0 symbol was represented by a pulse of width Tₚ followed by a quite period of T₀ seconds while the 1 symbol was represented by a pulse of width Tₚ followed by a quite period of T₁ seconds. For this test the proposed modulator circuit was employed with the test setup of FIG. 6. FIG. 13 shows waveforms acquired from the modulator as bits were transmitted for V_{low}=0.90 V_{oc}, Tₚ=10 μs , T₀=15 μs and T₁=40 μs. A measured bit error rate (BER) of 7.71×10⁻⁶ for 388,874 transmitted bits was obtained at a rate of 26.67 kbps.

A second action may be said to be “in response to” a first action independent of whether the second action results directly or indirectly from the first action. The second action may occur at a substantially later time than the first action and still be in response to the first action. Similarly, the second action may be said to be in response to the first action even if intervening actions take place between the first action and the second action, and even if one or more of the intervening actions directly cause the second action to be performed. For example, a second action may be in response to a first action if the first action sets a flag and a third action later initiates the second action whenever the flag is set.

To clarify the use of and to hereby provide notice to the public, the phrases “at least one of <A>, <B>, . . . and <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed.

While various embodiments have been described, it will be apparent to those of ordinary skill in the art that many more embodiments and implementations are possible. Accordingly, the embodiments described herein are examples, not the only possible embodiments and implementations.

What is claimed is:

1. A system comprising:
A solar cell;
A modulator connected to an output of the solar cell; and
an input configured to receive a signal, wherein
the signal being in a first state causes the modulator to modulate voltage output of the solar cell and cause the solar cell to perform optical transmission,
the signal being in a second state causes the modulator to cease modulation of the output of the solar cell.

2. The system of claim 1, wherein the modulator comprises a transistor and an op-amp in a feedback loop configuration.

3. The system of claim 2, further comprising a first switch controlled by the signal, the first switch selectively connecting the op-amp to either a modulation voltage or a voltage higher than the open contact voltage of the op-amp,
wherein the signal being in the first state connects the op-amp to a modulation voltage,
wherein the signal being in the second state connects the op-amp to a voltage higher than the open contact voltage of the op-amp.

4. The system of claim 3, further comprising a second switch controlled by the signal, the select switch selectively connecting the output of the solar cell to a DC to DC converter,
wherein the signal being in the first state disconnects the output of the solar cell from the DC to DC converter,
wherein the signal being in the second state connects the output of the solar cell to the DC to DC converter.

5. The system of claim 4, wherein the voltage higher than the open contact voltage of the op-ap is provided by the output of the DC to DC converter.

6. The system of claim 2, wherein he transistor is a metal-oxide-semiconductor field-effect transistor.

7. The system of claim 1, further comparing an optical receiver, wherein the optical receiver is configured to receive the optical transmission from the solar cell.

8. The system of claim 1, wherein the solar cell is a Gallium arsenide (GaAs) solar cell.
